(19) United States
(12) Patent Application Publication
(10) Pub. No.: US 2025/0040328 A1
(43) Pub. Date: Jan. 30, 2025

(54) EPITAXIALLY GROWN CONVERTER LAYER, OPTOELECTRONIC ARRANGEMENT AND METHOD FOR PRODUCING THE SAME

(71) Applicant: ams-OSRAM International GmbH, Regensburg (DE)

(72) Inventor: Tansen Varghese, Regensburg (DE)

(21) Appl. No.: 18/714,913

(22) PCT Filed: Dec. 2, 2022
(86) PCT No.: PCT/EP2022/084157

§ 371 Date: May 30, 2024

(30) Foreign Application Priority Data
Dec. 3, 2021 (DE) 10 2021 131 929.3

(51) Int. Cl. H01L 27/15

(52) U.S. Cl. CPC H01L 27/156

(57) ABSTRACT

In an embodiment an optoelectronic arrangement includes at least one vertical optoelectronic device with a first side and a second side, wherein at least parts of the second side form a main emission surface, and wherein the optoelectronic device is configured to emit light of a first wavelength from the main emission surface, an electrically conductive barrier structure at least partially surrounding the at least one vertical optoelectronic device and comprising sidewalls with a reflective surface, the reflective surface electrically isolated from sidewalls of the vertical optoelectronic device, a layer stack arranged on and bonded to the main emission surface and comprising a first epitaxially grown converter layer configured to convert the light of the first wavelength to light of a second wavelength and an optional conductive layer arranged on the main emission surface and electrically connecting a second contact with the electrically conductive barrier structure.

### CROSS-REFERENCE TO RELATED APPLICATIONS

This patent application is a national phase filing under section 371 of PCT/EP2022/084157, filed Dec. 2, 2022, which claims the priority of German patent application 10 2021 131 929.3, filed Dec. 3, 2021, each of which is incorporated herein by reference in its entirety.

### TECHNICAL FIELD

The present invention concerns an epitaxially grown converter layer, an optoelectronic arrangement having such layer and a method for processing the same.

### BACKGROUND

Optoelectronic devices become smaller and are now in the range of a few μm in diameter. Particularly for optoelectronic devices utilizing certain epi material systems, such as for example certain aluminum based semiconductors, the resulting μLEDs suffer from efficiency losses due to non-radiative recombination (NRR). Such NRR is caused by defects close to edge regions of an active layer containing aluminium, as such epi systems have a diffusion length for charge carriers in the range of the size of those μLEDs, and high non-radiative surface recombination. Various measures have been proposed to overcome the issues, like re-growth of the edges of the active region, quantum well intermixing and the like.

However, as size of pixels and consequently size of μLEDs becomes smaller, transfer processes become more challenging, as the transfer precision may vary, causing mispositioning. Finally, the different semiconductor materials generally used for the processing of green, blue, and red light comprise different electrical, thermal and aging characteristics, which make control of the optoelectronic devices and subsequently displays more difficult. Separate R, G and B arrays used in a system together do not completely prevent those issues.

### SUMMARY

Embodiments provide improved optoelectronic devices and displays.

In various embodiments, the inventor proposes to utilize an epitaxially grown converter layer for light conversion instead of a current triggered generation of light.

Such epitaxially grown planar converter layer comprise in some aspects a first wavelength selective layer, a second wavelength selective layer and an epitaxially grown semiconductor conversion layer in between. The epitaxially grown semiconductor conversion is processed based on a specific semiconductor material system. Potential suitable systems are based on ternary or quaternary semiconductor material like for example AlGaN, AlGaP, InGaN, InGaP, InGaAlN or InGaAlP. However, any epitaxially grown semiconductor structure that provides and active region suitable for light absorption and re-emission can be used for processing a semiconductor conversion layer.

The proposed idea makes use of the fact that semiconductor layers are capable of absorbing light of a certain wavelengths and subsequently re-emitting such light either at the same wavelength or-as proposed in the present case-with a different and longer wavelength. Consequently, such epitaxially grown semiconductor conversion layers are processed components, which, when pumped with light of a certain wavelength, will absorb the light and re-emit light of the different longer wavelength.

To enhance and support the absorption as well as the re-emission into a certain direction, the first wavelength selective layer is configured for a large transmittance of light with the first wavelength and configured for a large reflectance of light with a second wavelength. The second wavelength selective layer is configured for a large transmittance of light with a second wavelength and a large reflectance of light with the first wavelength.

The epitaxially grown converter layer in accordance with the proposed principle is therefore configured to trap pump light of the first wavelength within the certain area including the epitaxially grown semiconductor conversion layer, thus significantly increasing the probability for light conversion. Similarly, the first wavelength selective layer is configured to let light of the first wavelength-that is the pump light-pass, while reflecting the converted light. The second wavelength selective layer will reflect the pump light directing the light of the first wavelength back into the direction of the conversion layer while transmitting the converted light.

Such epitaxially grown planar converter layers are particularly suitable for use in displays, or in combination with μLEDs providing the pump light, by arranging those layers above the μLEDs for light conversion. A benefit of such approach is its small overall size, because conventional conversion layers require a large thickness to convert light with suitable conversion efficiency.

In contrast, the proposed epitaxially grown planar converter layer can be manufactured separately with an optimized bandgap, thickness, and doping profile for efficient conversion. With the additional coating and reflection layers arranged on both sides of the conversion layer, the absorption of light of the first wavelength outside the conversion layer itself can be reduced while at the same time charge carriers generated by light absorption are collected and directed towards the conversion layer itself for recombination and subsequent re-emission.

In this regard, the epitaxially grown semiconductor conversion layer comprises an active region configured for recombination of charge carriers. Those charge carriers are not injected into the active region like in conventional optoelectronic devices but generated by absorption of light of the first wavelength. The generated charge carriers, that is electrons and respective holes, are subsequently directed into the active region and recombine there again under emission of light. The wavelength of this light is given by the bandgap within the active region and can be adjusted to suit the needs. The epitaxially grown semiconductor conversion layer may comprise in some instances doping and bandgap profiles, which are configured to draw charge carriers towards of the active region. This therefore prevents recombination of the charge carriers outside the active region, thus improving the efficiency of the conversion.

In this regard, it should be noted that the epitaxially grown semiconductor conversion layer may comprises an active region like the ones in conventional optoelectronic devices. Such active region can comprise, a quantum well, a multi-quantum well structure or a simple pn-junction to name a few configurations. The composition, thicknesses and strain can be adjusted to provide the desired bandgap and therefore converted wavelength. In some examples, the active region of the epitaxially grown semiconductor conversion layer comprises a ternary or quaternary semiconductor material as already indicated above. Still, the proposed principle is based on passive conversion using absorption of pump light in contrast to direct charge carrier injection into the active region.

The epitaxially grown planar converter layer in accordance with the proposed principle can be manufactured in different sizes and is particularly suitable for conversion of blue pump light into green or red light, or green pump light into red light, using InGaN or InGaAlP conversion layer materials. InGaAlP has a relatively large diffusion length for charge carriers causing the issues for conventional μLEDs mentioned in the introductory part. With the proposed epitaxially grown planar converter layer, the overall size for the active layer is extended beyond the usual emission surface area as in conventional aluminum containing optoelectronic devices. Consequently, the influence of the larger diffusion length of charge carriers in such material is reduced, the quantum efficiency can be increased and together with a suitable grown conversion layer, a significant improvement over conventional aluminum containing optoelectronic devices is achievable.

In some aspects, at least one of the first and second wavelength selective layer comprises a DBR mirror. Using a DBR mirror provides a wavelength selective reflection and transmission, which is particularly suitable for trapping the light of the first wavelength, namely the pump light within the epitaxially grown conversion layer. It is also suitable for preventing light of the second wavelength from escaping in the wrong direction (towards the pump region).

The converter layers, including the active layer(s) and the layers on either side, can also be designed to be a resonator, with careful adjustment of the thicknesses and bandgap profiles, to prevent waveguiding (which leads to deleterious optical crosstalk) and enhance forward emission. The thickness of the converter layer can also be optimized otherwise to reduce optical crosstalk.

Another aspect concerns the edges or sidewalls of the epitaxially grown semiconductor conversion layer. While the conversion layer may be significantly larger compared to the dimension of conventional μLEDs, it is suitable in some instances to cover the edge of the semiconductor conversion layer with a dielectric passivation layer. In some other aspects, a regrowth layer is provided covering of the edge of the respective semiconductor conversion layer causing a shift in the bandgap close to an edge of the semiconductor conversion layer. As a further alternative, a quantum well intermixed area may be provided close to an edge of the semiconductor conversion layer, thus increasing bandgap. AN area with different doping profile may be provided close to an edge of the semiconductor conversion layer, thus increasing band bending and therefore the barrier to diffusion of carriers.

The above-mentioned measures change the electrical structure of the active region within the epitaxially grown semiconductor conversion layer preventing the charge carriers from reaching the edge of the conversion layer with the non-radiative recombination centers.

Intermixed areas or areas with different doping can also be provided outside the active region, and even in the case of a continuous converter layer, to prevent carrier diffusion to the next active region, thereby reducing deleterious electrical crosstalk.

These respective measures can be implemented separately from other measures taken to improve the quantum efficiency of the overall device and are not limited by any constraints during the processing of the optoelectronic device. In particular, the epitaxially grown planar converter layer can be manufactured independently and subsequently arranged and bonded to ono or more μLEDs. Furthermore, current distribution layer, or specific p-and n-doped layer for charge carrier transport are not required. The epitaxially grown planar converter layer with the conversion layer in between the wavelength selective layer is a fully passive component and does not require any external supply source for charge carrier injection.

In some instances, at least one of the first and second wavelength selective layer is a non-conductive layer. For example, one of the first and second wavelength selective layer may comprise one or more nonconductive layers with different refractive indices to provide the selectivity for the incident and emitted light. In some other aspects, the first wavelength selective layer may include an electrically conductive layer, particularly with a conductive surface opposite the epitaxially grown semiconductor conversion layer. In such case, the first wavelength selective layer with its conductive surface can be used as a common contact for an optoelectronic device providing the pump light of the first wavelength. Such approach enables a very tight and small implementation of an optoelectronic arrangement with full conversion capabilities.

In this regard, the second wavelength selective layer may include further functionality for directing or shaping light of the second wavelength that is the converted light. For example, the second wavelength selective layer is configured in some aspects for an angular filtering of light with a second wavelength. This may enable the epitaxially grown planar converter layer in accordance with the proposed principle to emit converted light in a certain direction and provide specific emission characteristics.

In some further instances, the epitaxially grown planar converter layer is configured as a resonator which serves to increase directionality of the converted light. By doing so, it may also reduce optical crosstalk between individual optoelectronic devices arranged to provide light to the epitaxially grown planar converter layer for conversion. In this regard, the thickness of the converter layer in the epitaxially grown planar converter layer can also be optimized to reduce optical crosstalk.

The inventor also proposes an optoelectronic arrangement with at least one vertical optoelectronic device with a first side and a second side. At least parts of the second side also forms a main emission surface of the vertical optoelectronic device. The optoelectronic device is configured for emitting light of the first wavelength from the main emission surface. This light with the first wavelength is also referred to as pump light.

In accordance with the proposed principle, an electric conductive barrier structure is at least partially surrounding the at least one vertical optoelectronic device and comprises sidewalls with the reflective surface. The reflective surface is electrically isolated from sidewalls of the vertical optoelectronic device to avoid a short circuit. The optoelectronic arrangement comprises a layer stack arranged on and particularly bonded to the main emission surface. The layer stack includes at least one epitaxially grown semiconductor converter layer that is configured to convert light with the first wavelength to light with the second wavelength. The layer stack also comprises a conductive layer, which electrically connects the second contact of the optoelectronic device with the conductive barrier structure.

The optoelectronic arrangement in accordance with the proposed principle provides light conversion of light with a first wavelength provided by the vertical optoelectronic device to a light of a second to wavelengths utilizing an epitaxially grown converter layer. The converter layer is directly arranged on the main emission surface and can be directly bonded to its surface. This will provide a small optoelectronic arrangement particularly suitable for display applications with μLEDs. The epitaxially grown converter layer may comprise different materials for converting light into different wavelengths. In this regard, the layer stack and/or the epitaxially grown semiconductor converter layer can be selectively structured to define red, green, and blue arrays on the same Indium containing array, wherein the blue or green light provided by the optoelectronic devices acts as so-called pump light. The pump light is absorbed and re-emitted in the epitaxially grown converter layer. The additional conductive layer of the layer stack in accordance with the proposed principle provides an electrical connection between the conductive barrier structure and the vertical optoelectronic device.

In some instances, the optoelectronic arrangement comprises at least two vertical optoelectronic devices which are spaced apart by the electrically conductive barrier structure. The layer stack now extends across the electrically conductive barrier structure covering the main emission surfaces of both vertical optoelectronic devices. In other words, the layer stack including the epitaxially grown converter layer may extend over a plurality of main emission surfaces of adjacent vertical optoelectronic devices. This is of particular benefit in certain aluminum containing material systems such as InGaAlP due to the large diffusion length and high non-radiative surface recombination. The converter layer has no edges close to the emission surfaces, therefore the influence of defects causing non-radiative recombination centers, which are usually present along the edges of an epitaxially grown and processed converter layer, decreases. At the same time, the efficiency of the epitaxially grown converter layer can be adjusted to maximize the light conversion from the light of the first wavelength provided by the vertical optoelectronic device into light of the second wavelength.

The layer stack can be bonded to the main emission surface by various means including preferably, direct bonding of the layer stack onto the main emission surface. As an alternative, a transparent conductive oxide particularly ITO can be utilized to facilitate the bonding. As a further alternative, an SIO₂ layer can be applied between of the bottom surface of the layer stack and in the main emission surface to facilitate the bonding. It is noted in this regard, an insulating layer like the SiO₂ layer facilitating of the bonding process can be additionally structured to provide electrical access to the second contact of the vertical optoelectronic device. This SiO₂ layer can be then form a part of the thin film optical stack meant for high transmittance of the pump light and high reflectance of the converted light, or part of the resonator structure meant to reduce crosstalk and increase directionality.

In some aspects, the layer stack comprises a second epitaxially grown converter layer, which is configured to convert light with the first wavelength into light with a third wavelength. In other words, the layer stack may comprise different converter layers, which are configured to convert pump light of the first wavelength into light of different wavelengths. Utilizing different epitaxially grown converter layers within the layer stack enables the implementation of an RGB pixel structure suitable for display devices. For example, the layer stack may comprise an area covering vertical optoelectronic devices with an epitaxially grown converter layer configured to convert the pump light of the first wavelength into red light. An adjacent vertical optoelectronic device emitting of the pump light may be covered by a second epitaxially grown converter layer configured to convert pump light into light of different wavelengths, for example, green light. A third vertical optoelectronic device configured to emit blue light as pump light remains uncovered by the layer stack and in particular uncovered by the epitaxially grown converter layer.

In some aspects, the different epitaxially grown converter layers must be stacked in a certain order within the layer stack to provide correct and full conversion. In some aspects, the second epitaxially grown converter layer is arranged between the first epitaxially grown converter layer and the conductive layer. Consequently, pump light may be converted first by the second epitaxially grown converter layer and this light is then subsequently converted by the first epitaxially grown converter layer. This requires that the second wavelength is longer than that of the third wavelength to enable the conversion. In cases, in which the third wavelength is longer than the second wavelength, the second epitaxially grown layer is above the first epitaxially a grown layer.

In some aspects, material of the conductive layer can form a part of the first and/or the second epitaxially grown converter layers. Likewise, material of the conductive layer can be the same material of the first and/or second epitaxially grown converter layer. In such aspects, the conductive layer forms an integral part of the epitaxially grown converter layer, which may further reduce the thickness of the overall layer stack and the optoelectronic arrangement. In addition, electrical and optical parameters can be adjusted during the growth of the layer stack.

In another aspect, the layer stack may comprise an outcoupling structure, which is arranged on one of the first and second epitaxially grown converter layers, but facing away from the main emission surface. The outcoupling structure can be wavelength selective and may, for instance facilitate and support the out coupling of light of the second and/or third wavelength. The outcoupling structure may also be reflective or comprise a higher reflectance for light with the first wavelength, thus reflecting the pump light of the first wavelength back into the conversion layer. In this regard, one of the first and second epitaxially grown converter layers may comprise a structure in accordance with the proposed principle, as indicated above. Hence, the first and/or second particularly grown converter layers may include wavelength selective layers to trap light with the first wavelength that is the pump light within the active region of the converter layer.

As already mentioned, one benefit of the proposed optoelectronic arrangement lies in the aspect that the area provided by the layer stack is larger than the main emission surface and the emission surface of the vertical optoelectronic device and conventional μLEDs in general. Consequently, the influence of the large diffusion length caused by the base material of the epitaxially grown converter layer is reduced in comparison to conventional μLEDs. As such one of the first and second converter layer of the layer stack may extend at least partially onto the electrically conductive barrier structure. The respective layer stack may also be bonded on to the electrically conductive barrier structure, and in particularly connects the barrier structure electrically to provide an electrical contact to the vertical optoelectronic device. In some aspects, the conductive layer of the layer stack is structured in a region above the electrically conductive barrier structure. The structure may facilitate various aspects, for instance improving the electrical conductivity between the conductive layer and the barrier structure. This may be suitable if the barrier structure comprises different material than the conductive layer.

In another aspect, one of the epitaxially grown converter layers is structured in the region above the electrically conductive barrier structure. The structuring above the barrier structure may reduce optical or electrical crosstalk between adjacent optoelectronic arrangements. In addition, structuring may allow to arrange different epitaxially grown converter layers side by side onto several adjacent vertical optoelectronic devices. In some aspects, the conductive layer of the layer stack is not structured and extends across several adjacent optoelectronic devices thus forming a common contact to supply adjacent several optoelectronic devices.

An area of the conductive layer of the layer stack may be larger than the respective first or second epitaxially grown converter layers. In such case, a protruding part of the conductive layer may be in electrical contact with the barrier structure. In such case, the epitaxially grown converter layer may have a size comparable to the size of the main emission surface or be slightly smaller.

Some aspects of the proposed principle relate to the following issue for certain epitaxially grown converter layers. Particularly charge carrier in layers with certain aluminium containing semiconductor material comprise a relatively large diffusion length, and high non-radiative surface recombination, causing issues at edge regions in the active region of the conversion layer. Consequently, the epitaxially grown converter layer may comprise a dielectric passivation layer covering edge regions of the converter layer. In an alternative solution, a regrowth layer can be provided covering the edge regions of the epitaxial grown converter layer causing a shift in the bandgap close to the edge regions. As a further alternative, a quantum well intermixed area or an area with altered doping profile can be provided closer to edge regions of the conversion layer increasing the bandgap or band bending, respectively, in said area. Intermixing and altered doping can also be provided to reduce carrier diffusion between adjacent emission regions, even in the case of continuous converter layers.

In some aspects, the conductive layer of the layer stack may comprise a conductive transparent material, in particular ITO or any other transparent oxide. In some other aspects, the first or second epitaxially grown converter layer may comprise a ternary or quaternary semiconductor material for example InGaN, InGaP, AlGaP, AlGaN, InGaAlP and InGaAlN. The first epitaxially grown converter layer or the second epitaxially grown converter layer comprise a thickness which is sufficiently large to enable full conversion. This will provide emission of light with substantially a single wavelength from the top surface of the layer stack. Alternatively, the converter layer may be thinner to deliberately provide a mixed light signal, for example, to generate white light.

Some aspects concern the relation and dimensions of the vertical optoelectronic device, the barrier structure and the layer stack, respectively. In some aspects, the main emission surface of the optoelectronic device is larger than the first side of the vertical optoelectronic device. In other words, the main emission surface may be larger than the surface of the at least one vertical optoelectronic device opposite the main emission surface. In such cases, the vertical optoelectronic device comprises tapered sidewalls opening up in the direction of the main emission surface. Such tapering may comprise further benefits like the reflection of light onto the sidewalls into the direction of the main emission surface, thus increasing the efficiency of the device. In addition, the actual area for light generation within the active region of the vertical optoelectronic device is smaller than the main emission surface and/or the area of the layer stack covering the main emission surface.

The electrically conductive barrier structure may comprise in some instances an internal conductive material covered by a reflective material. The reflective material covers the sidewall surfaces to reflect incident light from the vertical optoelectronic device towards the main emission surface. In this regard, the electrically conductive barrier structure may comprise different materials, in particular a core including a conductive material that is different from the reflective material covering the sidewall surface. In some aspects, the reflective material covering the sidewall surface comprises a metal, while the internal core of the respective conductive barrier structure comprises a doped semiconductor material. The reflective metal can also be used as an internal core as well as for the sidewall surfaces. In all cases, however, there is an insulating material or multiple layers of different insulating materials, at the sidewalls that separate any metal from the semiconductor. This can combine with the reflecting metal to form a metal-dielectric mirror.

In some further aspects, the conductive barrier structure adjacent to the layer stack may comprise at least partially a material which is configured for absorbing light of the first or second wavelength. The material configured for absorbing light can be any absorber, including for example: a metal or metal alloy that can also facilitate the conductivity of the barrier structure, such as for example providing an ohmic contact to the conductive layer. This material adjacent to the layer stack within the barrier structure is suitable to prevent optical or electrical crosstalk between adjacent optoelectronic arrangements.

In this regard, a cover portion may be arranged above the layer stack. It covers at least a portion of the layer stack adjacent to or located on the electrically conductive barrier structure. The cover portion may facilitate various functionalities, for example the absorption of light emitted from the layer stack above the barrier structure, and the reduction of the diffusion length of carriers within the converter layer. In addition, the cover portion may comprise a reflective surface to direct converted light from the layer stack. Furthermore, the cover portion may comprise tapered sidewalls, in particular following a sidewall of the barrier structure. This will allow forming and shaping of the emitted converted light from the layer stack. A reflective layer on the sidewalls of the covered portion supports the direction and emission of converted light. In some instances, the cover portion includes a material for absorbing light of the first or second wavelength. The material may be arranged on top of portions of the layer stack above the barrier structure, further supporting the reduction of electrical and/or optical crosstalk between adjacent optoelectronic arrangements.

The cover portion can be conductive and connected to the electrically conductive barrier structure by one or more vias through the layer stack.

In another aspect, the first contact of the vertical optoelectronic device comprises a highly reflective material for light of the second wavelength and optionally for light of the first wavelength. This will enable the pump light as well as the generated converted light with the second wavelength to be reflected towards the main emission surface.

The optoelectronic arrangement in accordance with the proposed principle can further comprise an insulation layer, located on a side of the at least one vertical optoelectronic device and the barrier structure facing away from the main emission surface. The insulation layer comprises a plurality of conductive vias electrically connecting the first contact and the electrically conductive barrier structure, respectively. The additional insulating layer separates the optoelectronic devices and the conductive barrier structures from a backplane, with its via contacting the respective contact on the backplane The backplane comprises control and supply circuitry for the optoelectronic arrangement.

Consequently, the optoelectronic arrangement comprises in some aspects a backplane substrate including control circuitry and supply circuitry for the at least one optoelectronic device. The backplane substrate for a display or a μLED display array is required to supply control circuitry for the respective μLEDs that are formed by the vertical optoelectronic device structures. In some instances, the backplane is of a different material compared to the μLEDs or the barrier structure. An insulating layer in between the optoelectronic devices and the backplane substrate may therefore also facilitate bonding, such as direct bonding, in addition to electrically isolating, wherever necessary, the μLEDs from the backplane substrate.

In some aspects, the first contact comprises a metal material and is connected to the p-side of the at least one vertical optoelectronic device. Likewise, the second contact comprises a metal and/or an n-doped material and is connected to the n-side of the at least one vertical optoelectronic device. Of course, p-side and n-sides of the vertical optoelectronic devices can also be switched depending on the manufacturing a method.

To facilitate and improve current injection into the vertical optoelectronic device, the first or second contacts may comprise a doped current distribution layer. In another aspect, the at least one vertical optoelectronic device is based on GaN or AlGaN material, which is configured for the emission of light with the wavelengths smaller than 600 nm. In other words, the at least one vertical optoelectronic device is configured to emit blue or green light, which is subsequently converted by the layer stack into a green or red light.

Another aspect relates to a display comprising an optoelectronic arrangement in accordance with the proposed principle. As mentioned above, the optoelectronic arrangement includes a first plurality of vertical optoelectronic devices configured for the emission of light with a first wavelength smaller than 600 nm The wavelength can be any wavelength shorter than the converted light, but there are less Stokes losses for longer wavelengths—less losses for green. Also, the pump devices may have different efficiencies. The layer stack comprises a first epitaxially grown converter layer configured to convert light to light in the range of 600 to 700 nm. The display further includes a second plurality of electrical optoelectronic devices being configured for the emission of light with a first wavelength smaller than 600 nm or as stated above, but not being covered by the layer stack. As a result, the display is now capable of emitting blue or green and red light, wherein the red light be in the range of 600 nm to 670 nm is generated by the epitaxially grown converter layer.

In a further aspect, the layer stack also includes a second epitaxially grown converter layer which is configured to convert light of the first wavelength light to light with a wavelength in the range of 500 nm to 560 nm. Hence, the second epitaxially grown converter layer is configured to convert blue light into green light. In some instances, the two epitaxially grown converter layers are spatially separated from each other, for example, forming substantially parallel stripes, or squares, circles and other shapes covering a plurality of vertical optoelectronic devices. Together with the optoelectronic devices not covered by the layer stack, the optoelectronic arrangement together with the uncovered vertical optoelectronic devices forms a plurality of pixels for the display.

Another aspect of the proposed principle concerns that the processing of an optoelectronic arrangement.

In one aspect, a growth substrate is provided and subsequently processed to form a functional semiconductor layer stack with an active region thereupon. The functional semiconductor layer stack can have one or more differently doped layers including different doping profiles where necessary. The active region is configured to emit light of a first wavelength and may comprise a quantum well structure, a multi-quantum well structure or any other suitable light emitting layer. In this regard, light of the first wavelengths may include a wavelength smaller than 500 nm, which is generally considered blue light, or between 500 and 560 (green).

In a subsequent step, the functional semiconductor layer stack is structured to form a plurality of μLEDs. These μLEDs are formed as vertical μLEDs and comprise a first contact and a second contact on different opposing sides. Furthermore, the second contact may also provide a main emission surface. To facilitate the structuring of the functional layer stack, a mesa structure may be generated within the functional semiconductor layer stack thus separating the plurality of μLEDs from each other. The recess is then further processed to implement the barrier structure between the adjacent μLEDs. The barrier structure comprises a conductive core electrically insulated from sidewalls of the plurality of μLEDs, but nevertheless electrically accessible from a top side adjacent to the main emission surface.

Then, the layer stack is bonded to the main emission surface of the plurality of μLEDs as well as to the top side of the barrier structure. The layer stack comprises a first epitaxially grown, converter layer, which is configured to absorb light of the first wavelength and remit light of a second wavelength.

The resulting optoelectronic arrangement is configured to generate light for subsequent conversion into the desired wavelength, wherein the conversion is facilitated by an epitaxially grown converter layer specifically for that purpose. In contrast to methods, in which conventional converter material is used, the epitaxially grown converter layer can have a significantly smaller thickness. In addition, certain material systems, particularly including aluminum-based semiconductors are suited for the epitaxially grown converter layer and a passive conversion, in comparison to conventionally processed μLEDs based on such material system.

Bonding the layer stack to the main emission surface is facilitated by a direct bonding process of the layer stack onto the main emission surface and the barrier structure. Alternatively, a transparent conductive oxide, for example, ITO may be used for facilitating the bonding process. As a further alternative, an insulating transparent layer can be arranged between the bottom surface of the layer stack and the main emission surface, wherein the insulating transparent layer comprises a plurality of via or through holes to connect the second contact of the plurality of μLEDs to the conductive layer.

In another aspect, the layer stack also comprises a second epitaxially grown converter layer, which is configured to convert light of the first wavelength into light of a third wavelength. Stacking different epitaxially grown converter layers on top of each other enables an optoelectronic arrangement processed by the proposed method to convert light with a first wavelength,—that is the pump light—into different colors. Hence, an array of pixels is comprehensible having a plurality of μLEDs with different epitaxially grown converter layers bonded thereto for generating blue, green and red light.

The second epitaxially grown converter layer may be arranged between the first epitaxially grown converter layer and the conductive layer in some aspects. Alternatively, it may be arranged above the first epitaxially grown converter layer. The precise arrangement of the second epitaxially grown converter layer is dependent on the respective material of the first and second epitaxially grown converter layer ensuring that material providing the light with the longest wavelength is on top of the layer stack.

Another aspect concerns the bonding of the layer stack to the main emission surface. For this purpose, the conductive layer may be deposited on the main emission surface and the barrier structure electrically connecting the conductive core of the barrier structure with the second contact of the plurality of μLEDs. Then, the layer stack is bonded to the conductive layer. As an alternative, the layer stack comprises a conductive layer and the first epitaxially grown converter layer. In such case, the conductive layer is bonded to the main emission surface and the conductive core of the barrier structure with the converter layer facing the main emission surface. The conductive layer can also be a part of the epitaxial growth structure of the pump μLEDs.

In all cases, the conductive layer provides the electrical contact between the second contact of the plurality of LEDs and the internal conductive core of the barrier structure. In this regard, material of the conductive layer can form a part of the epitaxially grown pump layer or the first and second epitaxially grown converter layer. The conductive layer may also comprise the same material as the epitaxially grown pump layer or the first or second epitaxially grown converter layer. Such aspects may reduce the thickness of the epitaxially grown converter layer and provide additional functionality within the layer stack.

In a further aspect, the layer stack also comprises an outcoupling structure, which is arranged on the first or second epitaxially grown layer facing away from the main surface. The outcoupling structure may simplify the outcoupling of converted light, and provide directional functionality, emission enhancement or other functions.

In some aspects, the conductive layer of the layer stack or the first or second epitaxially grown converter layers are structured in the region above the electrically conductive barrier structure. Depending on the requirements and needs for an optoelectronic arrangement processed by the proposed method, the structuring reduces further optical or electrical crosstalk between the different adjacent μLEDs. In this regard, the epitaxially grown converter layer may extend over a plurality of μLEDs in a certain direction and as such can be formed as stripes, squares, circles or other shapes after bonding onto the plurality of μLEDs. Consequently, pixel arrays with a plurality of μLEDs formed in rows or columns configured to emit converted light with the same wavelength, or μLEDs of different wavelengths distributed as desired, can be achieved.

In some aspects, the step of structuring the functional semiconductor layer stack comprises the formation of a plurality of recesses causing tapered sidewalls along the plurality of μLEDs. The tapered sidewalls are a result of the etching process forming the plurality of recesses. The tapered sidewalls are further opened in the direction of the main emission surface. In other words, size or diameter of the main emission surface is larger than the respective diameter of the active layer of the respective μLEDs or the first contact thereof. Following the etching of the plurality of recesses, an insulating layer may be deposited on at least some portions of the tapered sidewalls.

The barrier structure can then be formed by depositing an internal conductive material as well as the reflective material into the formed plurality of recesses. The internal conductive material as well as the reflective material can be different, for instance including an absorbing metal and a reflective metal, respectively. As an alternative, both materials can be the same and include a reflective metal, for example.

In some aspects, a cover portion is deposited and structured above the layer stack after the bonding process and the removal of the growth substrate of the converter layers. The cover portion covers at least a portion of the layer stack above the conductive core of the barrier structure. In other words, portions of the layer stack adjacent to the barrier structure, are covered by the cover portion from the top side and the barrier structure from the bottom side. Depositing a cover portion further reduces optical and electrical crosstalk between adjacent μLEDs and layer stack, but also support directing converted light generated in the layer stack.

The cover portion may comprise tapered sidewalls. A reflecting layer may be arranged on the sidewalls of the cover portion as well. In some aspects, the cover portion is conductive and connected to the conductive core of the barrier structure by one or more vias through the layer stack.

In some further aspects, the μLEDs processed by the proposed method have first contacts with a highly reflective material. The highly reflective material will reflect light generated in the active layer of the plurality of μLEDs directing the reflected light to the main emission surface. In a further aspect, an insulating layer is arranged on a side of the at least one μLED and the barrier structure facing away from the main emission surface. The insulating layer comprises a plurality of conductive vias that electrically connect the first contact and the internal core of the barrier structure, respectively. In a further aspect, a backplane substrate having control and supply circuitry is arranged on the insulating layer and electrically connected to the conductive vias.

In the following an optoelectronic arrangement, an epitaxially grown planar converter layer, a display, and a method for processing an optoelectronic arrangement is proposed as items:
1. Optoelectronic arrangement, comprising:
at least one vertical optoelectronic device with a first side and a second side, at least parts of the second side forming a main emission surface, the optoelectronic device configured for emitting light of a first wavelength from the main emission surface;
an electrically conductive barrier structure at least partially surrounding the at least one vertical optoelectronic device and comprising sidewalls with a reflective surface, said reflective surface electrically isolated from sidewalls of the vertical optoelectronic device;
a layer stack arranged on and particularly bonded to the main emission surface and comprising a first epitaxially grown converter layer that is configured to convert light of the first wavelength to light of a second wavelength;
an optional conductive layer arranged on the main emission surface and electrically connecting the second contact with the electrically conductive barrier structure.
2. Optoelectronic arrangement according to item 1, comprising at least two vertical optoelectronic devices spaced apart by the electrically conductive barrier structure, wherein the layer stack extends across the electrically conductive barrier structure covering the respective main emission surfaces of the at least two vertical optoelectronic devices.
3. Optoelectronic arrangement according to item 1 or 2, wherein bonding of the layer stack to the main emission surface is facilitated by at least one of:
Direct bonding of the layer stack onto the main emission surface;
a transparent conductive oxide, particular ITO;
a dielectric layer, particularly of high index such as Nb₂O₅ or TiOₓ, between the bottom surface of the layer stack and the main emission surface.
4. Optoelectronic arrangement according to any of items 1 to 3, wherein the layer stack comprises a second epitaxially grown converter layer configured to convert light of the first wavelength into light of a third wavelength.
5. Optoelectronic arrangement according to item 4, wherein the second epitaxially grown converter layer is arranged between the first epitaxially grown converter layer and the conductive layer or the emission surface; or
above the first epitaxially grown converter layer.
6. Optoelectronic arrangement according to any of items 1 to 5, wherein material of the conductive layer forms a part of the first and/or second epitaxially grown converter layer; or wherein the conductive layer forms a part of the least one vertical optoelectronic device; and/or the conductive layer comprises the same material as the first and/or second epitaxially grown converter layer.
7. Optoelectronic arrangement according to any of items 1 to 6, wherein the layer stack comprises an outcoupling structure arranged on the first and/or second epitaxially grown converter layer facing away from the main emission surface.
8. Optoelectronic arrangement according to any of items 1 to 7, wherein the first and/or second epitaxially grown converter layer comprises an epitaxially grown planar converter layer according to any of items 35 to 45.
9. Optoelectronic arrangement according to any of items 1 to 8, wherein the first and/or the second converter layer of the layer stack extends at least partially onto the electrically conductive barrier structure.
10. Optoelectronic arrangement according to any of items 1 to 9, wherein the conductive layer of the layer stack is structured in a region above the electrically conductive barrier structure.
11. Optoelectronic arrangement according to any of items 1 to 10, wherein the first and/or second epitaxially grown converter layer is structured in a region above the electrically conductive barrier structure.
12. Optoelectronic arrangement according to any of items 1 to 11, wherein one of the conductive layer of the layer stack and the first and/or second epitaxially grown converter layer is structured in a region above the electrically conductive barrier structure.
13. Optoelectronic arrangement according to any of items 1 to 12, wherein an area of the conductive layer of the layer stack is larger than the first and/or second epitaxially grown converter layer, wherein a protruding part of the conductive layer is in electrical contact with the electrically conductive barrier structure.
14. Optoelectronic arrangement according to any of items 1 to 13, wherein first and/or second epitaxially grown converter layer comprises at least one of:
a dielectric passivation layer covering an edge region above the electric conductive barrier structure;
a regrowth layer covering an edge region above the electric conductive barrier structure causing a shift in the bandgap close to the edge;
quantum well intermixed area close to an edge region above the electric conductive barrier structure increasing the bandgap in the area;
different doping profile close to an edge region above the electric conductive barrier structure changing the band bending in the area;
a quantum well intermixing in an area of the converter layer above the electric conductive barrier structure;
an altered doping profile in an area of the converter layer above the electric conductive barrier structure changing the band bending in the area.
15. Optoelectronic arrangement according to any of items 1 to 14, wherein the conductive layer of the layer stack comprises a conductive transparent material, in particular ITO or another transparent oxide.
16. Optoelectronic arrangement according to any of items 1 to 15, wherein the first and/or second epitaxially grown converter layer comprises a quaternary semiconductor material, in particular containing Al, in particular InGaAlP or InGaAlN, or a ternary semiconductor material, in particular InGaP or InGaN.
17. Optoelectronic arrangement according to any of items 1 to 16, wherein the first epitaxially grown converter layer comprises a thickness sufficiently large to enable full conversion.
18. Optoelectronic arrangement according to any of items 1 to 17, wherein the main emission surface is larger than the first side; or wherein the main emission surface is larger than the surface of the at least one optoelectronic device opposite the main emission surface.
19. Optoelectronic arrangement according to any of items 1 to 18, wherein sidewalls of the barrier structure are tapered opening in the direction of the main emission surface.
20. Optoelectronic arrangement according to any of items 1 to 19, wherein the electrically conductive barrier structure comprise an internal conductive material and a reflective material covering its sidewall surfaces.
21. Optoelectronic arrangement according to item 20, wherein the internal conductive material is different from the reflective material covering the sidewall surface of the at least one optoelectronic device.
22. Optoelectronic arrangement according to any of items 1 to 20, wherein the electrically conductive barrier structure is a reflective metal.
23. Optoelectronic arrangement according to any of items 1 to 22, wherein barrier structure adjacent to the layer stack comprises at least partially a material configured for absorbing light of the first and/or second wavelength.
24. Optoelectronic arrangement according to any of items 1 to 23, further comprising a cover portion arranged above the layer stack, optionally bonded thereto, and covering at least a portion of the layer stack adjacent to the electrically conductive barrier structure.
25. Optoelectronic arrangement according to item 24, wherein the cover portion is larger than the topmost surface of the electrically conductive barrier structure, thereby covering at least a portion of the second contact of the at least one vertical optoelectronic device.
26. Optoelectronic arrangement according to item 24 or 25, wherein the cover portion comprises at least one of:
tapered sidewalls, in particular following the sidewalls of the barrier structure;
a passivation layer on its sidewalls;
a material configured for absorbing light of the first and/or second wavelength;
a material configured for reflecting light of the first and/or second wavelength located on the sidewalls of the cover portion.

p1 . Optoelectronic arrangement according to item 24 or 26, wherein the cover portion is conductive and connected to the electrically conductive barrier structure, in particular by one or more vias though the layer stack
28. Optoelectronic arrangement according to any of items 1 to 27, wherein the first contact comprises a highly reflective material, for light of first wavelength and optionally for light of the second wavelength.
29. Optoelectronic arrangement according to any of items 1 to 28, further comprising an insulation layer located on a side of the at least one vertical optoelectronic device and the electrically conductive barrier structure facing away from the main emission surface, wherein the insulation layer comprising a plurality of conductive via electrically connected to the first contact and the electrically conductive barrier structure, respectively.
30. Optoelectronic arrangement according to any items 1 to 29, further comprising a backplane substrate arranged on the insulating layer and comprising one of control circuitry and supply circuitry for the at least one vertical optoelectronic device.
31. Optoelectronic arrangement according to any items 1 to 30, wherein the first contact is connected to the p-side of the at least one vertical optoelectronic device; and the second contact comprises an n-doped material and/or connected to the n-side of the at least one vertical optoelectronic device.
32. Optoelectronic arrangement according to any items 1 to 31, wherein at least one of the first and the second contacts comprises a doped current distribution layer.
33. Optoelectronic arrangement according to any items 1 to 32, wherein the at least one vertical optoelectronic device is based on ZnSe, GaN, InGaN or AlGaN material configured for the emission of light with a wavelength smaller than 600 nm.
34. Optoelectronic arrangement according to any items 1 to 33, wherein the conductive layer is part of the layer stack or wherein the layer stack is bonded to the conductive layer, extending over a plurality of vertical optoelectronic devices.
35. Epitaxially grown planar converter layer, comprising
a first wavelength selective layer;
a second wavelength selective layer;
an epitaxially grown semiconductor conversion layer comprising a converter material for absorbing light of a first wavelength and converting it into light of a second wavelength, arranged between the first and second wavelength selective layer, respectively;
wherein the first wavelength selective layer is configured for a large transmittance of light with the first wavelength and a large reflectance of light with the second wavelength; and
wherein the second wavelength selective layer is configured for a large reflectance of light with the first wavelength and a large transmittance of light with the second wavelength.
36. The epitaxially grown planar converter layer according to item 35, wherein at least one of the first and second wavelength selective layer comprises a DBR mirror.
37. The epitaxially grown planar converter layer according to any of items 35 to 36, wherein the epitaxially grown semiconductor conversion layer comprises an active region configured for recombination of charge carriers, particularly generated by absorption of light of the first wavelength.
38. The epitaxially grown planar converter layer according to item 37, wherein at least the epitaxially grown semiconductor conversion layer and optionally the wavelength selective layers 41 and 42 have doping profiles configured to draw charge carriers towards the active region.
39. The epitaxially grown planar converter layer according to any of items 35 to 38, wherein the epitaxially grown semiconductor conversion layer comprises
a quantum well
a multi-quantum well structure; or a
a bulk material layer.
40. The epitaxially grown planar converter layer according to any of items 35 to 39, wherein the epitaxially grown semiconductor conversion layer comprises a quaternary semiconductor material, in particular containing Al, in particular InGaAlP or InGaAlN, or a ternary, in particular InGaP or InGaN.
41. The epitaxially grown planar converter layer according to any of items 35 to 40, wherein the epitaxially grown semiconductor conversion layer comprises at least one of:
a dielectric passivation layer covering an edge of the semiconductor conversion layer;
a regrowth layer covering the edge causing a shift in the bandgap close to an edge of the semiconductor conversion layer;
a quantum well intermixed area close to an edge or in certain other areas of the semiconductor conversion layer increasing the bandgap. different doping profile close to an edge or in certain other areas of the semiconductor conversion layer changing the band bending.
42. Epitaxially grown planar converter layer according to any of items 35 to 41, wherein at least one of the first and second wavelength selective layer is a nonconductive layer or layer stack.
43. Epitaxially grown planar converter layer according to any of items 35 to 42, wherein the first wavelength selective layer is an electrically conductive layer, particularly with a conductive surface opposite the epitaxially grown semiconductor conversion layer.
44. Epitaxially grown planar converter layer according to any of items 35 to 43, wherein the second wavelength selective layer is configured for angular filtering of light with the second wavelength.
45. Epitaxially grown planar converter layer according to any of items 35 to 44, configured to form a resonator for increasing directionality of light of the second wavelength.
46. Display comprising:
an optoelectronic arrangement according to any of items 1 to 34 with a first plurality of vertical optoelectronic devices configured for the emission of light with a first wavelength smaller than 600 nm; wherein the layer stack comprises first epitaxially grown converter layer configured to convert light to light in the range of 600 nm to 660 nm; and
with a second plurality of vertical optoelectronic devices being configured for the emission of light with a first wavelength smaller than 600 nm and not being covered by the first epitaxially grown converter layer.
47. Display according to item 46 wherein the layer stack comprises a second epitaxially grown converter layer configured to convert light of the first wavelength to light.
48. Display according to item 46 or 47, wherein first epitaxially grown converter layer extends over the first plurality of vertical optoelectronic devices along a direction, wherein the second plurality of vertical optoelectronic devices is arranged adjacent to the first plurality of vertical optoelectronic devices.
49. Display according to item 46 or 47 wherein a conductive layer extends over the first and second plurality of layers, the conductive layer electrically connected to at least one barrier structure located between the first and second plurality of vertical optoelectronic devices.
50. Method for processing an optoelectronic arrangement, comprising the steps of:
Providing a growth substrate;
Processing a functional semiconductor layer stack with an active region, said active region configured to emit light of a first wavelength;
Structuring the functional semiconductor layer stack to form a plurality of μLEDs, said μLEDs comprising a first contact and a second side main emission surface;
Providing a barrier structure between adjacent μLEDs, wherein the barrier structure comprises a conductive core insulated from sidewalls of the plurality of μLEDs, but accessible from a top side adjacent to the main emission surface;
Bonding a layer stack to the main emission surfaces of the plurality of μLEDs, said layer stack comprising a first epitaxially grown converter layer configured to absorb light with the first wavelength and re-emit light with a second wavelength.
51. Method according to item 50, wherein bonding a layer stack to the main emission surface is facilitated by at least one of:
Direct bonding of the layer stack onto the main emission surface;
a transparent conductive oxide, particular ITO;
a dielectric layer, particularly of high index such as Nb₂O₅ or TiOₓ, between the bottom surface of the layer stack and the main emission surface.
52. Method according to item 50 or 51, wherein the layer stack comprises a second epitaxially grown converter layer configured to convert light of the first wavelength into light of a third wavelength.
53. Method according to item 52, wherein the second epitaxially grown converter layer is arranged between the first epitaxially grown converter layer and the conductive layer; or above the first epitaxially grown converter layer.
54. Method according to any of items 50 to 53, wherein bonding a layer stack to the main emission surfaces comprises:
Depositing a conductive layer on the main emission surface and the barrier structure, electrically connecting the conductive core of the barrier structure with the second contact of the plurality of μLEDs;
Bonding the layer stack to the conductive layer.
55. Method according to any of items 50 to 53, wherein bonding a layer stack to the main emission surfaces comprises:
Providing the layer stack comprising a conductive layer and the first epitaxially grown converter layer;
Bonding the conductive layer to the main emission surfaces and the conductive core of the barrier structure.
Bonding the layer stack to the main emission surfaces, the main emission surface comprising a conductive layer being part of the functional semiconductor layer stack.
56. Method according to any of items 54 and 55, wherein material of the conductive layer forms a part of the first and/or second epitaxially grown converter layer; or
the conductive layer comprises the same material as the first and/or second epitaxially grown converter layer.
57. Method according to any of items 50 to 56, wherein the layer stack comprises an outcoupling structure arranged on the first and/or second epitaxially grown converter layer facing away from the main emission surface.
58. Method according to any of items 50 to 57, wherein the first and/or second epitaxially grown converter layer comprises an epitaxially grown planar converter layer according to any of items 35 to 45.
59. Method according to any of items 50 to 58, wherein one of the conductive layers of the layer stack and the first and/or second epitaxially grown converter layer is structured in a region above the conductive core of the barrier structure.
60. Method according to any of items 50 to 59, wherein an area of the conductive layer of the layer stack is larger than the first and/or second epitaxially grown converter layer, wherein a protruding part of the conductive layer is in electrical contact with the electrically conductive barrier structure.
61. Method according to any of items 50 to 60, wherein first and/or second epitaxially grown converter layer comprises at least one of:
a dielectric passivation layer covering an edge region above the electric conductive barrier structure;
a regrowth layer covering an edge region above the electric conductive barrier structure causing a shift in the bandgap close to the edge;
quantum well intermixed area close to an edge region above the electric conductive barrier structure increasing the bandgap in the area;
different doping profile close to an edge region above the electric conductive barrier structure changing the band bending in the area;
a quantum well intermixing in an area of the converter layer above the electric conductive barrier structure;
an altered doping profile in an area of the converter layer above the electric conductive barrier structure changing the band bending in the area.
62. Method according to any of items 50 to 61, wherein the step of structuring the functional semiconductor layer stack comprises:
Forming a plurality of recesses causing tapered sidewalls of the plurality of μLEDs, wherein the tapered sidewalls are opening in the direction of the main emission surface;
Depositing an insulating layer on at least some portions of the tapered sidewalls.
63. Method according to item 62, wherein the step of providing a barrier structure comprises:
Depositing an internal conductive material and a reflective material into the plurality of recesses; wherein the internal conductive material is different from the reflective material;
and/or
a reflective metal.
64. Method according to any of items 50 to 63, further comprising
Depositing a cover portion arranged above the layer stack, and covering at least a portion of the layer stack adjacent to the barrier structure.
65. Method according to item 64, wherein the cover portion comprises at least one of:
tapered sidewalls, in particular following the sidewalls of the barrier structure;
a passivation layer on its sidewalls;
a material configured for absorbing light of the first and/or second wavelength;
a material configured for reflecting light the first and/or second wavelength located on the sidewalls of the cover portion.
66. Method according to any of items 64 to 65, wherein the cover portion is conductive and connected to the conductive core of the barrier structure, in particular by one or more via though the layer stack.
67. Method according to any of items 50 to 66, wherein the first contact comprises a highly reflective material, for light of first wavelength and optionally for light of the second wavelength.
68. Method according to any of items 50 to 67, further comprising the step of Providing an insulating layer located on a side of the plurality of μLEDs and the barrier structure facing away from the main emission surface, wherein the insulation layer comprising a plurality of conductive via electrically contacting the first contact and the conductive core of the barrier structure, respectively.
69. Method according to any of items 50 to 68, further comprising the step of Providing a backplane substrate arranged on the insulating layer and comprising one of control circuitry and supply circuitry for the at least one vertical optoelectronic device.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 illustrates a schematic view of a first optoelectronic arrangement illustrating some aspects, the proposed principle;

FIG. 2 shows a schematic view of a second optoelectronic arrangement illustrating some further aspects of the proposed principle;

FIG. 3 illustrates a schematic view of a third optoelectronic arrangement showing some further aspects of the proposed principle;

FIG. 4 shows a schematic view of an alternative fourth optoelectronic arrangement in accordance with some aspects, the proposed principle;

FIG. 5 illustrates a schematic view of a fifth optoelectronic arrangement in accordance with some aspects, the proposed principle;

FIG. 6 shows a schematic view of a 6th optoelectronic arrangement in accordance with some aspects, the proposed principle;

FIG. 7 shows a schematic view of a seventh alternative optoelectronic arrangement with some other aspects of the proposed principle;

FIG. 8 shows a schematic view of an embodiment of an epitaxially grown planar converter layer in accordance with some aspects, the proposed principle that is suitable to be implemented in a proposed optoelectronic arrangement;

FIG. 9 shows a schematic view of some further aspects of an epitaxially grown planar converter layer in accordance with the proposed principle;

FIG. 10A illustrates a schematic sideview of a display device in accordance with some aspects, the proposed principle;

FIGS. 10B and 10C show top views of a display device in accordance with some aspects, the proposed principle; and

FIGS. 11 to 19 illustrate an embodiment of a method for processing an optoelectronic arrangement in accordance with some aspects, the proposed principle.

### DETAILED DESCRIPTION OF ILLUSTRATIVE EMBODIMENTS

The following embodiments and examples disclose different aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the Figures can be combined with each other without further ado, without this contradicting the principle according to embodiments of the invention. Some aspects show a regular structure or form. It should be noted that in practice slight differences and deviations from the ideal form or shape may occur without, however, contradicting the inventive idea.

In addition, the individual Figures and aspects are not necessarily shown in the correct size or dimensions, nor do the proportions between individual elements have to be essentially correct. Some aspects are highlighted by showing them enlarged. However, terms such as “above”, “over” “below”, “under” “larger”, “smaller” and the like are correctly represented with regard to the elements in the Figures. So, it is possible to deduce such relations between the elements based on the Figures.

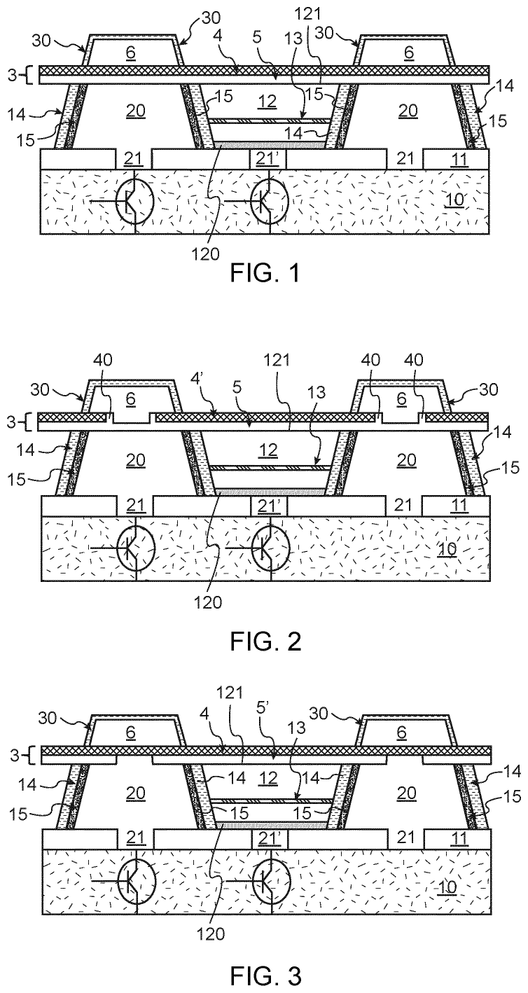

FIG. 1 illustrates an optoelectronic arrangement in a cut view, which is arranged on a semiconductor backplane for control and power supply of the optoelectronic arrangement. In particular, backplane 10 implemented in a silicon-based technology comprises control circuitry and supply circuitry. Silicon-based technology is well understood and allows the implementation of such control and power supply circuitry with relatively small dimensions.

However, different characteristics render it difficult to arrange different semiconductor materials and particularly III-V semiconductor on silicon. For this purpose, the optoelectronic arrangement comprises an insulating layer 11 portion, which is configured for adjustment of the different surface characteristics. With the insulating layer 11 (and further measures not shown herein), it is possible to arrange the optoelectronic arrangement directly on to the backplane substrate 10. The insulating layer also enables bonding such as direct metal-dielectric hybrid bonding.

The optoelectronic arrangement comprises a vertical optoelectronic device formed as a so-called μLED. A μLED is an optoelectronic device that comprises a very small lateral dimension with its emission surface a being in the range of a few micrometers. For example, a μLED can have a lateral dimension of smaller than the 70 μm, and in particular smaller than 20 μm. In some instances, a μLED has a lateral dimension between 500 nm and 20 μm. A vertical optoelectronic device in accordance with the present application is defined as μLED with its contact areas being arranged on the different sides of the device.

Referring back to FIG. 1, the optoelectronic arrangement also comprises a barrier structure 20, which surrounds the vertical optoelectronic device formed as μLED 12 from all sides. Barrier structure 20 is conductive but also isolated from the vertical optoelectronic device arranged in between.

The optoelectronic device 12 includes a bottom or first contact 120 as well as the top or second side 121 opposite the bottom contact. The bottom contact 120 is electrically connected to a via 21′ which extends through the insulating layer 11 and connects a respective contact portion on the surface of backplane 10. Via 21′ is filled with a conductive material, thus providing an electrical connection to vertical optoelectronic device 12. Bottom contact 120 also includes a current distribution functionality for spreading the current over the whole p-side of the μLED 12. The p-side is arranged on bottom contact 120 and is coupled to active area 13 of the vertical optoelectronic device. The active area 13 may include a single a quantum well, a simple pn junction or a multi-quantum well structure. In the present example, the vertical optoelectronic device and μLED 12 is based on the Gallium-Nitride (GaN) semiconductor material system, which is suitable to generate light with bluish or greenish wavelengths. i.e., in the range between 380 nm to 570 nm.

The vertical optoelectronic device 12 comprises a tapered surface with its sidewalls being contacted by an insulating layer 14. The tapered surface opens towards the direction of the main emission surface being also being the second side 121. In other words, bottom contact 120 comprises a smaller diameter compared to the second side 121 and main emission area. Passivation layer 14 includes a transparent insulating material like SiO₂ or any other suitable material. It covers the surface and is located between the optoelectronic device 12 and the reflective material 15. Passivation layer 14 can be a part of the surrounding barrier structure 20.

Barrier structure 20 comprises a conductive internal core, which is connected to a plurality of vias 21 in insulating layer 11. The conductive vias 21 are also connected to respective contact areas on backplane substrate 10. Conductive via 21 as well as the internal conductive core of barrier structure 20 may include a metal. Due to the tapered surface of the vertical optoelectronic device 12, the barrier structure also comprises a tapered surface, however with a decreasing diameter with an increasing distance from the insulating layer. μLED 12 surrounded by the barrier structure comprises an increasing diameter with increasing distance from insulation layer 11.

In accordance with the proposed principle, the main emission surface of the vertical optoelectronic device 12 including second side 121 is now covered with the layer stack 3 including conductive layer 5, as well as epitaxially grown converter layer 4. In particular conductive layer 5 is directly adjacent to second side 121 of the vertical optoelectronic device and extends from the main emission surface of the device all the way to the barrier structure 20 surrounding the device. As illustrated in the example of FIG. 1, layer stack 3 also extends further and onto adjacent vertical optoelectronic devices not directly illustrated in this example. By doing so, layer stack 3 comprises a significantly larger surface compared to the main emission surface area of the vertical optoelectronic device and μLED 12 in this arrangement. Likewise, the epitaxially grown converter layer 4 also includes a significantly larger surface compared to the area of the active region 13 in device 12.

Conductive layer 5 of layer stack 3 is electrically coupled to the internal core of barrier structure 20 and electrically connected to the top or second side 121 of the vertical optoelectronic device 12. Conductive layer 5 can be a semiconductor layer grown as part of the epitaxy of μLED 12 or a transparent conductive oxide like ITO and the like with a decreased spreading resistance and contact resistance to suitable metals. In operation of the device, current may flow through via portions 21 into the internal core of the conductive barrier structure 20 and from there into conductive layer 5 and into the optoelectronic device via the interface between conductive layer 5 and μLED 12, thereby generating light in the active layer 13.

The light is emitted in all directions including towards the reflective layer 15 covering the conductive barrier structure. From there it is reflected towards the main emission surface due to its a tapered structure. Light being generated in the active region and into first contact 120 is reflected from the contact surface and re-directed towards the main emission surface. The light through the main emission surface is absorbed in the epitaxially grown layer 4 and converted into a light with the second wavelength. Light with the second wavelength comprises a longer wavelength than light generated within active regions 13.

On top of layer stack 3 within the region above barrier structure 20 cover portion 6 with a reflective layer 30 is provided. Cover portion 6 is processed on layer stack 3. As illustrated in FIG. 6, cover portion 6 may also include a tapered surface with decreasing diameter with increasing distance from layer stack 3.

As shown in FIG. 1, the relevant aspects lie in the conversion of light in an epitaxially grown converter layer, wherein the light is generated separately in an active region of the vertical optoelectronic device. The epitaxially grown converter layer comprises different materials depending on the desired converted light. For light in the red portion of the spectrum, the epitaxially grown converter layer comprises an Indium and/or aluminum containing material and can be used for conversion of blue or greenish light into red light. Due to the large diffusion length of such materials non-radiative recombination centers usually would occur close to edge portions of such an active layer. In the present example, the conversion is initiated not by carrier injection as in conventional optoelectronic devices based on the semiconductor material containing Indium, but by absorption and re-emission of converted light.

The fact that the converter layer extends across all the pixels in the array, which can be in the range of hundreds of microns or several mm in size, and only has an edge at the edge of the array, means that non-radiative recombination centres are far from the μLED pixels of the array. The epitaxially grown converter layer passively generates a reddish or greenish light by absorption and re-emission, but not by carrier injection and direct generation itself.

FIG. 2 illustrates an alternative embodiment of an optoelectronic arrangement in accordance with the proposed principle. Elements with similar or the same functionality comprises same reference signs. In this arrangement, the epitaxially grown layer 4′ is structured at a position corresponding and above the core of the conductive barrier structures. In particular, the epitaxially grown layer structure is separated within the core of the conductive barrier structure, wherein the removed material of the epitaxially grown layer 4′ is replaced by an absorbing and conductive material of cover layer 6. Edges of the epitaxially grown layer 4′ are covered by a passivation layer 40.

The structuring of epitaxially grown layer 4′ may result in non-radiative recombination centers in the area closer to the edges of the structured layer. However, passivation layer 40 can include a regrowth or intermixing or other passivation process, resulting in a change of the bandgap close to the structured edges within the epitaxially grown layer 4′. As a result, charge carriers being generated by the absorption of light provided by the vertical optoelectronic device is prevented from reaching the non-radiative recombination centers. Still, as illustrated in FIG. 1, the lateral dimension of layer 4′ is larger than the main emission surface with second side 121 reducing the problem caused by the increased diffusion length in Indium containing material systems. The benefit of structuring the epitaxially grown converter layer within the conductive barrier structure lies in a reduced optical crosstalk.

Converted or unconverted light within the epitaxially grown converter Layer 4′extending laterally into the barrier structure 20 will reach passivation layer 40 and the structured area of the converter Layer 4′. The absorbing material of cover portion 6 will prevent light from extending through the barrier structure and crosstalk into adjacent μLEDs. Like the previous embodiment, the bottom and side surface of μLED 12 are reflective directing light towards the main emission surface and second side 121.

FIG. 3 shows an alternative example of an optoelectronic arrangement in accordance with some aspects of the proposed principles. In contrast to the previous embodiments, the conductive layer 5 is structured and divided into different elements between the conductive barrier structure 20. In particular, absorbing material of conductive barrier structure 20 will reach into the conductive layer 5′ adjacent to the epitaxially grown converter layer 4. Similar as in the previous example, light coupled into the epitaxially grown converter layer 4 and traveling into the conductive barrier structure comprises a higher probability of being absorbed within the barrier structure 20 and cover portion 6.

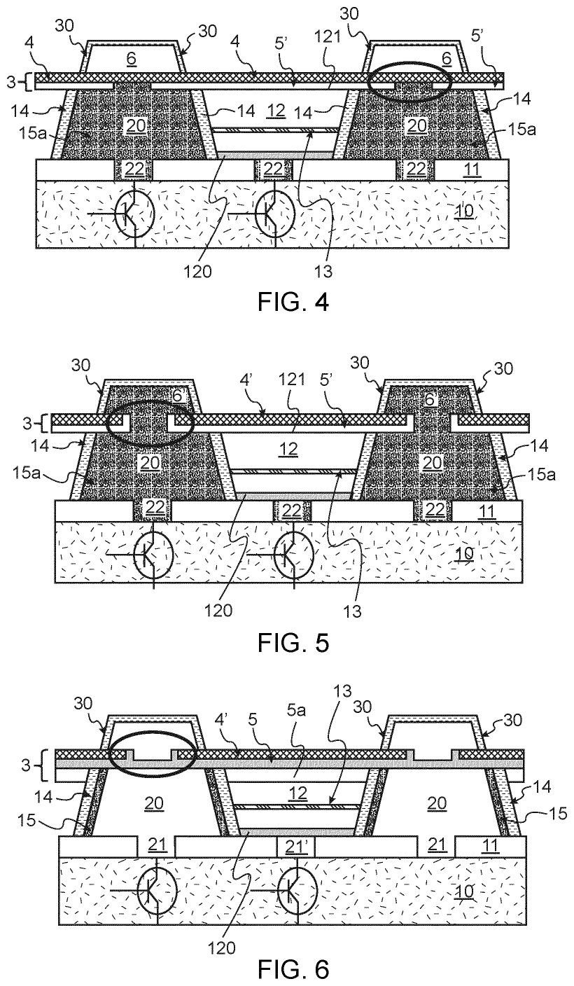

In the previous examples, the conductive barrier structure is formed often with a conductive core including a doped semiconductor material, which also comprises characteristics of absorbing light from the epitaxially grown converter layer 4. However, in some instances, in which the distance between two adjacent μLED's 12 is sufficiently large, the conductive barrier structure 20 can be implemented using a pure metal as its inner core. Examples of optoelectronic arrangements with a conductive barrier 20 with an inner core made of metal are illustrated in the FIGS. 4 and 5, respectively.

FIG. 4 shows a plurality of metal via 22 and 22′ through the insulating layer 11 connecting the conductive barrier structure 20 and the μLED 12 with the backplane substrate 10. The metal may comprise cooper, silver, gold or any other suitable material with a low resistivity value. Conductive barrier structure 20 includes an inner core 15 formed of metal material. The core is covered and electrically insulated by a passivation layer 14. The conductive and metal core is connected to conductive layer 5′, which in turn contacts the rest of the μLED 12. A cover portion 6 is adjacent to layer stack 3 in the vicinity of conductive barrier structure 20. The cover portion 6 comprises an absorbing material for preventing optical crosstalk between adjacent μLEDs 12.

As a further aspect, cover portion 6 as well as conductive barrier structure 20 can be formed by the same conductive and reflective metal as illustrated in FIG. 5. In addition, cover portion 6 is in direct contact with conductive barrier structure 20 by separating the respective layer stack 3 completely within the barrier structure. As indicated edge portions of layer stack 3 are covered by a passivation layer reducing the non-radiative recombination centers within the epitaxially grown converter layer 4′. Conductive layer 5 is connected electrically from its bottom side within conductive barrier structure 20.

Like the other examples, cover portion 6 comprises a slightly smaller diameter in comparison to barrier structure 20, resulting in a larger opening and a recessed passivation layer 30 with regards to passivation layer 14 on the sidewall of barrier structure 20. The slight recess of passivation layer 30 with regards to passivation layer 14 will result in a larger surface area of the epitaxially grown converter layer 4′ in comparison to the main emission surface of μLED 12. As a result, the area in which converted light can exit the converter layer 4 can be enlarged resulting in an improved conversion efficiency.

FIG. 6 illustrates a further example of an optoelectronic arrangement in accordance with some aspects. In this example, layer stack 3 comprises an epitaxially grown converter layer 4′, a conductive layer 5 beneath as well as a further layer 5a located below the conductive layer 5. Conductive layer 5 is a transparent conductive oxide while layer 5a is the top surface of μLED 12. In this example, instead of the top epitaxial 5a layer of the pump μLED extending between adjacent μLEDs, the transparent conductive oxide layer 5a extends between adjacent μLEDs and forms the common spreading layer for all the μLEDs in the array.

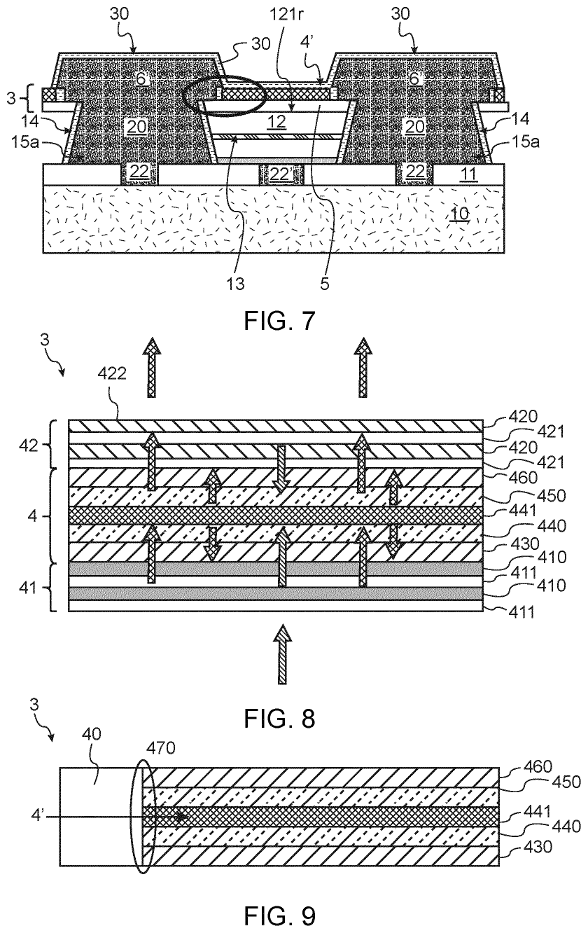

FIG. 7 illustrates a slightly different approach of an optoelectronic arrangement in accordance with the proposed principle. In this exemplary embodiment, layer stack 3 with its epitaxially grown converter layer 4′ comprises a slightly smaller area than the main emission surface 121 of μLED 12. μLED 12 includes a tapered structure with an increasing diameter at an increasing distance from insulating layer 11. Conductive layer 5 is not connected to the conductive barrier structure from the bottom side as in the previous examples. Rather cover portion 6′ connects to conductive layer 5 by an extension of cover portion 6′ from the top side. This is an actual contrast to the previous embodiment, in which conductive material 5 is connected from its bottom side that is the side facing the main surface area 121 of μLED 12.

The electrical connection from the top side requires a reduction of the overall area of epitaxially grown converter layer 4 as illustrated in FIG. 7. Passivation layer 30 separates the edge portions of epitaxially grown converter layer 4 from cover portion 6′ and conductive barrier structure 20. Conductive barrier structure 20 comprises a conductive reflective material connected to a via 22 in insulating layer 11.

The optoelectronic arrangement in accordance with the proposed principle as outlined in the previous Figures can be coupled together to form pixels in a pixel array of a display. For this purpose, the different optoelectronic arrangements include different layer stacks for converting the light provided by the μLEDs 12 into different colors.

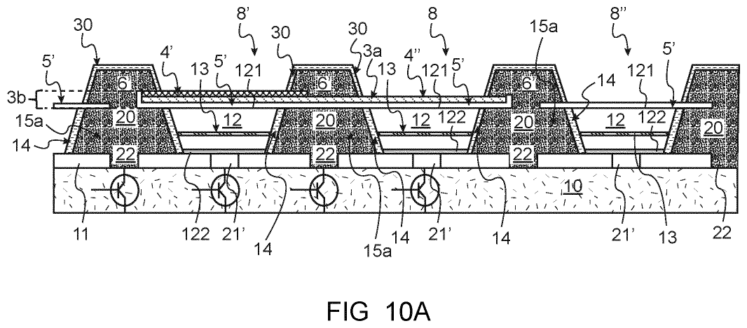

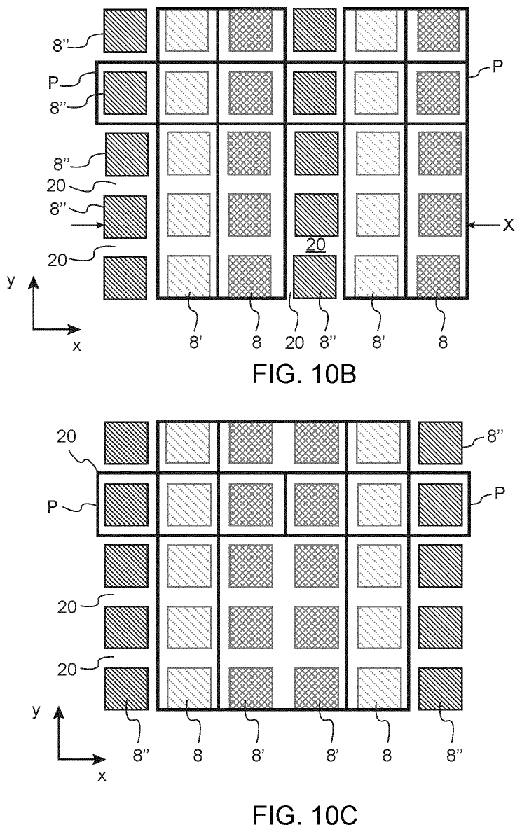

FIG. 10A illustrates an exemplary embodiment of such an arrangement suitable for implementation into a display and configured for generating blue, green, as well as red light. The latter two wavelengths are generated by a passive conversion of blue pump light into green and red light, respectively. The arrangement comprises three elements 8, 8′ and 8″, each of them including a μLEDs. The elements are forming subpixels of a pixel. Element 8 is configured for emission of green light, while element 8′ is configured for emission of red light. The last element 8″ will emit blue light in operation, said blue light not being converted. Each element 8, 8′ and 8″ comprises a μLED 12 implemented as a vertical optoelectronic device having an active layer 13 between the p-doped side and n-doped side, respectively.

The p-doped side is connected via a current distribution layer 122 to conductive via 21′ in insulating layer 11. Each vertical μLED 12 comprises a tapered sidewall, on which a passivation layer 14 is arranged. The passivation layer 14 is part of a conductive barrier structure 20 surrounding each of the μLEDs of elements 8, 8′ and 8″. Barrier structure 20 comprises a reflective conductive material as its core with the passivation layer 14 covering the core and insulating is from the sidewalls of μLED 12. The conductive material of barrier structures 20 are electrically connected to a plurality of vias 22 through insulation layer 11. Electrically conductive vias 22 and 21′ connect respective elements of the backplane substrate 10.

The top right element 8″ of the arrangement comprises the μLED 12 with the active layer 13 comprises an Indium based material like InGaN and is configured to emit blue light. The top contact also forms the main surface area 121 for the μLED 12. The conductive layer 5 is arranged on the top of the μLED 12, extending from the main emission surface into the surrounding barrier structure 20, electrically connecting the barrier structure 22 to μLED 12. In operation of this μLED, blue light is emitted towards the main emission surface. Light that is directed towards the current distribution layer 122 or the passivation layer 14 is reflected at the respective surfaces and directed towards the main emission surface.

The middle element 8 is adjusted for converting blue light generated by μLED 12 within active layer 13 of μLED 12 into green light. μLED 12 of element 8 comprises the same structure as for element 8″ or element 8′. This has a benefit, because the μLED array can be processed as a single piece, which will simplify the manufacturing process. A layer stack 3a is directly adjacent to the top surface 121 of μLED 12, thereby forming element 8. Layer stack 3a comprises conductive layer 5, as well as epitaxially grown converter layer 4′ comprising a doped material suitable for converting pumped blue light into green light. InGaN based materials can be used for example.

As shown herein, the layer stack 3a with epitaxially grown layer 4′ and conductive layer 5 also extends completely through the barrier structure 20 between elements 8 and 8′ thereby also covering top surface 121 of the top left μLED 12 being part of element 8′. A second epitaxially grown converter layer 4′ is provided on top of epitaxially grown converter layer 4″ in said element 3′. The second epitaxially grown converter layer 4′ is adjusted to convert blue as well as green light into red light emitting the red light away from the green converter layer 4″. Such a structure is possible, as the epitaxially grown converter Layer 4′ is adjusted to absorb blue and green light coming from the active region 13 as well as epitaxially grown layer 4″, respectively.

The layer stack 3a and 3b with their continuous planar epitaxially grown converted layer are extended over a plurality of μLED 12 to form a plurality of elements 8 and 8′. The μLEDs not covered by an epitaxially grown, converter layer, but simply covered by transparent conductive layer 5 is shown with the top right element 8′ in FIG. 10A forms an element configured to emit blue light.

FIGS. 10B and 10C illustrate a top view of a pixel array as part of a larger displays, with elements 8, 8′ and 8″. The elements are arranged to form pixels P of the display, each pixel comprising 3 subpixels of elements 8, 8′and 8″. The cut view along the X line provides the illustration of FIG. 10A.

As shown in FIG. 10B the epitaxially grown converter layers form a longitudinal strip extending over a plurality of μLEDs forming the respective elements 8 and 8′. Consequently, the influence of the diffusion length of charge carrier in the epitaxially grown converter layer, particularly for element 8′ is reduced, as the epitaxially grown converter layer comprises a significantly longer undisturbed material along the y-direction. Similarly, the converter layer for the green subpixel covers a plurality of elements 8 along the y-direction. However, the material for passive conversion of green light does not suffer from the same issues as the aluminum containing material for red light conversion.

The epitaxially grown converter layer for the green and red pixels can be manufactured separately and then bonded together before being bonded to the array of μLEDs 12. The growth substrate of the top converter layer is then removed. The epitaxially grown converter layer is then subsequently structured to remove layer 4′or both layers 4′ and 4″ from the layer stack to provide the uncovered portion for elements 8″ and the covered portion for element 8 with the conversion layer for the green converted light. Alternatively, to the previously mentioned process or additionally, the conductive layer 5 is manufactured during growth of the array. Subsequently, the various different converter layers are formed as stripes, squares, circles or other shapes and arranged on the conductive layer in the correct positions.

FIG. 10C illustrates an alternative to further reduce the effect of the diffusion length. In this example subpixels 8′ for generating converted red light are arranged next to each other for each separate pixel P. As a result, the influence on the diffusion length in the epitaxially grown material containing aluminum is reduced even along the x-axis. The conversion layer for the generation of greenlight 4″does not have the same issue and therefore can simply form longitudinal stripes along the Y direction.

The display in accordance with the proposed principle and illustrated in FIGS. 10A to 10C comprises the benefit that the array for the optoelectronic devices can be implemented based on a single semiconductor material and is subsequently processed by bonding a respective epitaxially grown conversion layer on top of a plurality of subpixels. The distance between the respective μLEDs 12 forming elements 3″ is given by the conductive barrier structure 20. The respective array of μLEDs can either be monolithically integrated or placed as separate μLEDs a respective substrate.

Some exemplary embodiments for epitaxially grown converter layers suitable for bonding to the respective μLEDs in accordance with the proposed principles are illustrated in FIGS. 8 and 9, respectively.

As mentioned previously, the epitaxially grown converter layer is based on a layer stack comprising a conversion layer 4 arranged between a first wavelength selective layer 41 and a second wavelength selective layer 42. First wavelength selective layer 41 is implemented as a DBR mirror including a plurality of alternating transparent layers 411 and 410, respectively. Likewise, wavelength selective layer 42 comprise a plurality of alternating transparent layers 421 and 420, respectively. The material of layers 41 and 42 are transparent and comprise different refractive indices. Alternating transparent layers 411 and 410 forming the first wavelength selective layer 41 are selected and adjusted in such way that the first wavelength selective layer 41 is substantially transparent for incident light of the first wavelengths that is the pump light. However, converted light, as indicated by the small arrows towards the wavelength selective layer 41 are reflected into the conversion layer 4.

The alternating materials for 420 and 421 of wavelength selective layer 42 are configured in such a way that they form a transparent wavelength selective layer for the converted light indicated by the respective arrows while pump light not converted within the conversion layer 4 is reflected into the conversion layer 4. In other words, the pump light is trapped with this arrangement inside the conversion layer 4 while the converted light is able to leave the layer stack 3 through the main emission surface 422. Apart from the wavelength selection functionality, the second wavelength selective layer 42 may also comprise functionality for directing the converted light in a certain direction, by design of the layer materials and thicknesses. The emission surface 422 can also either be structured or comprise further elements like photonic structures or meta lenses to enhance the functionality of the layer stack 3.

Conversion layer 4 comprises a semiconductor material suitable for absorbing light of certain wavelengths and re-emitting light of a different and longer wavelengths. Such behavior is present in many semiconductor-based material systems, which can be used for light conversion. For example, conversion layer stack 4 may comprise a plurality of doped layers of different bandgaps 430 and 440, which are positioned adjacent to an active region 441. Differently doped layers of different bandgaps 450 and 460 can also be provided on top of the active region 441. The semiconductor stack 4 is similar to conventional μLEDs with the exception that its doping profile as well as the active region 441 in between are particularly adjusted for absorbing pump light of the first wavelength.

Charge carriers generated within any of layers of conversion layer 4 are drawn by the respective doping and bandgap profiles of layers 430, 440 and 450, 460, respectively, towards the active region 441 for subsequent recombination. As the active region 441 comprises at least one direction or dimension which is significantly larger compared to conventional μLEDs, the influence of the diffusion length or other crystal defects resulting in a non-radiative recombination is reduced.

FIG. 9 illustrates a more detailed view of a second embodiment of conversion layer 4′, in which the lateral dimension is reduced similar to conventional μLEDs. In such cases, the edge region 470 of the layer stack 4′ is passivated by layer 40, covering the non-radiative recombination centers. The passivation layer 40 can cause a shift of the respective bandgap within the active region 441 to slightly higher levels which will cause an electric potential preventing the charge carriers from reaching the non-radiative recombination centers in the edge region 470. The processing of the passivation layer 40 is similar to the conventionally regrowth or quantum well intermixing approaches. In fact, quantum well intermixing as well as regrowth techniques can be applied to conversion layer 4 and 4′ in a similar fashion during processing the epitaxially grown conversion layers. This type of processing can also be provided to the continuous converter layer in between μLEDs, to reduce the diffusion of carriers between the μLEDs.

As already indicated above, the pixel array of a plurality of μLEDs can be implemented and processed separately from the epitaxially grown and converter layer 3. However, as shown in the exemplary embodiments of FIG. 1 to FIGS. 6 one aspect of the proposed principle lies in the fact that the area of the active region 13 in the μLEDs 12 is actually smaller than the area of the epitaxially grown conversion layer covering the top surface of μLEDs 12. This is due to the tapered surfaces which are generated by respective mesa structuring during the processing of the μLED array.

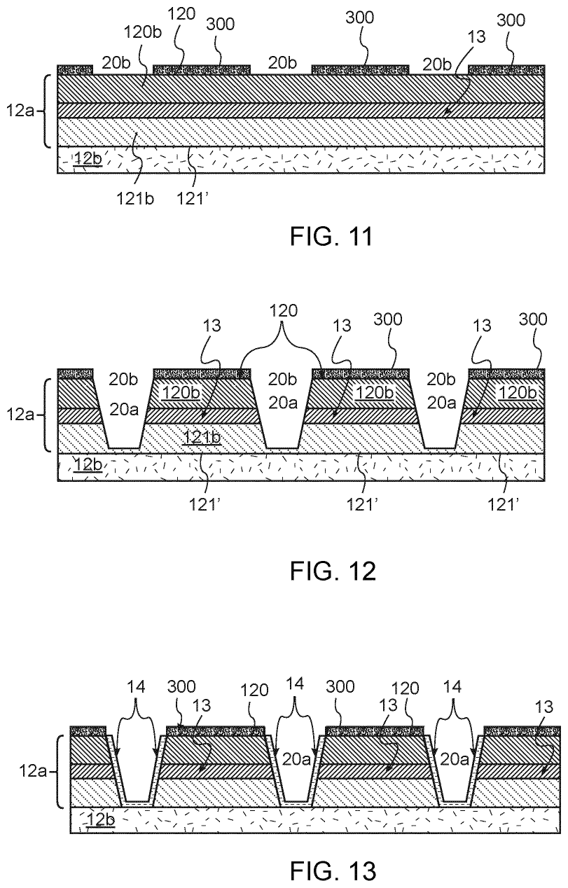

FIGS. 11 to 19 illustrate an exemplary embodiment for processing a functional layer stack providing a plurality of μLEDs 12 suitable for coverage with an epitaxially grown conversion layer. The μLEDs processed therein are based on a semiconductor material which emits bluish or greenish light in operation, for example InGaN. Epitaxially grown layer stack containing Indium and/or aluminum-based semiconductor material can be bonded directly to the main emission surface of the μLEDs providing a direct conversion. The level of conversion (full or half) is adjustable by selecting the proper thickness and electrical and optical properties of the conversion layer as well as the thickness, electrical and optical properties of the adjacent layers.

FIG. 11 illustrates the first few steps of the process of manufacturing an optoelectronic arrangement in accordance with the proposed principle. A growth substrate 12b is provided, on which a layer stack 12a is deposited. Growth substrate 12b may comprise a suitable growth material like sapphire or any other suitable material for growing the layer stack 12a. One or more sacrificial layers, nucleation layers, growth buffers or any other semiconductor layers having certain functionalities are provided between the growth substrate 12b and the first n-doped layer 121b. Those layers are summed with reference 121′. A sacrificial layer may be suitable if the respective lattice constant between of the semiconductor layer stack 12a and the growth substrate 12b comprises mismatch causing potential crystal defects reducing the overall quantum efficiency of the layer stack.

As also indicated in FIG. 11, surface interface and layers 121′ between growth substrate 12b and the first doped layer 121b will later be utilized to a provide the top surface of the μLED for the optoelectronic arrangement.

First n-doped layer 121b includes an n-doped material and comprises depending on the requirements a doping profile towards the active region 13 for current distribution, current transport and injection. In some instances, the n-doped layer 121b comprises a doped Gallium Nitride material, which can be deposited on the growth Sapphire substrate 12b. An active region 13 is grown on top of first doped layer 121b. Active region 13 may comprise one or more quantum wells configured to emit light. A second doped layer 120b is deposited on top of active region 13. The doped layer 120b is the p-doped GaN layer also comprising a profile suitable for current distribution and current injection into the active region 13.

The existing layer stack 12a is further processed to provide a plurality of the μLEDs configured to emit blue light or green light in operation. First, a transparent conductive oxide (TCO) such as ITO is deposited to form the p-contact 120 to the semiconductor. A structured photo resist layer 300 is provided on TCO layer 120. The TCO layer 120 will form the bottom contact of the processed μLEDs in the areas where the photoresist 300 remains after structuring. As illustrated in FIG. 11 structured photo resist layer 300 comprises certain recesses 20b, whereas the TCO layer 120 and the top surface of the second semiconductor layer 120b is exposed.

Referring now to FIG. 12, layer stack 12a is then mesa structured in a subsequent step, by etching the exposed portions of the surface of 120 through the recesses in the photo resist 300. The etching process is a mostly anisotropic etching process which leads to tapered sidewalls of recesses 20a through the layer stack 12a. As indicated in FIG. 12, the etching process is stopped shortly before the growth substrate 12b leaving the layer 121′ unetched. In this regard, layers 121′ may comprise an etch stop to prevent further etching.

Referring to FIG. 13, the sidewalls of the recesses are treated to remove crystal and other defects caused by the etching process. Then, a passivation layer 14 is deposited covering the sidewalls of the recess 20a. The bottom portion of the respective recesses 20a can either be left free of a passivation layer or also passivated as illustrated, but in such a case requires re-opening in a subsequent step (see FIG. 17). Passivation layer 14 may include SiO₂ or any other suitable isolating material.

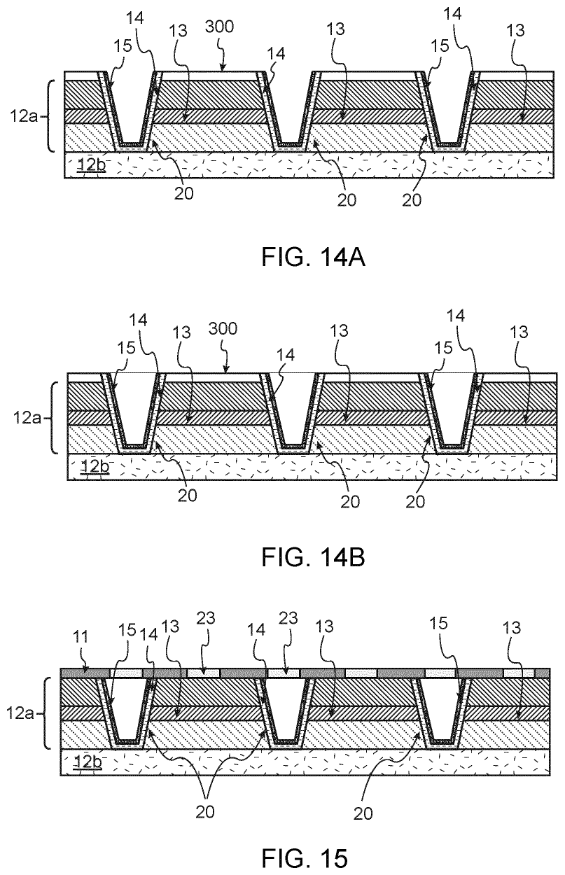

In the next subsequent steps shown in FIG. 14A and 14B, the passivated recesses 20a are filled with a conductive metal and semiconductor material, respectively. In a first step sidewalls of the passivation layer 14 are covered by a reflective metal layer 15, also covering the bottom the surface of the respective recesses 20a.

Then, a conductive material is filled into the remaining portion of the recesses 20a and polished to obtain a flat surface flush with the top TCO surface. Any photoresist 300 can be removed before or after this process. The conductive material within the recess may comprise a metal or metal-semiconductor alloy. It should be able to form an ohmic contact with the layer 121′. It also has certain absorbing characteristics for light of the first and second wavelength. In contrast to the reflective layer 15, the remaining conductive material forms internal core of the barrier structure 20 including a light absorbing material.

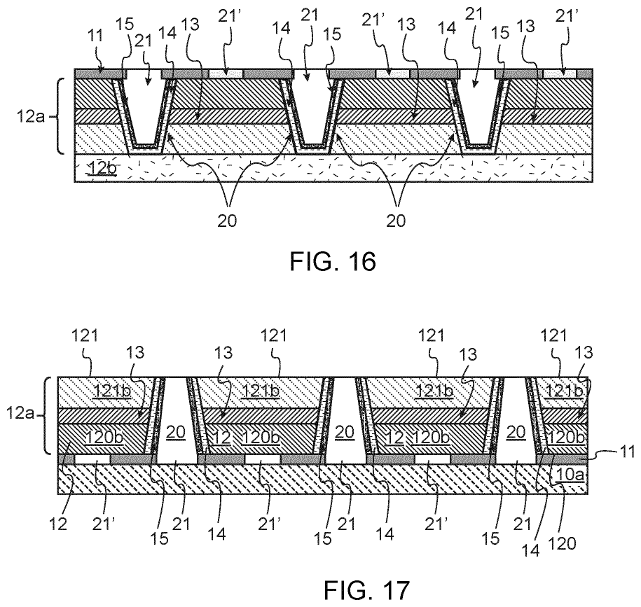

FIG. 15 depicts a subsequent step, in which a continuous insulating layer 11 is applied on the surface of the second layer 120b and the filled recess portions forming the barrier structure 20. The insulating layer 11 is subsequently structured to open various recesses 23, exposing either the conductive surfaces of the internal core of barrier structure 20 or the top surface 120 of the TCO layer. The recesses in the insulating layer 11 are filled with a reflective conductive material 21 and 21′ forming an electrical connection. The result of this process is illustrated in FIG. 16 showing the connection via with the reflective metal 21 connecting the internal core of barrier structure 20 as well as contacts 21′ contacting the first contact to the TCO p-contact.

In a subsequent step, a re-bonding process is performed by attaching an optionally temporary carrier 10a to the surface of insulating layer 11 and the contact material of the via 21 and 21′and subsequently removing the growth substrate 12b. The carrier 10a can also be the permanent Backplane substrate. The sacrificial layer portions and parts of portion 121b can also be optionally removed to expose the second side 121 as well as the conductive internal core and its reflective material 15 of barrier structure 20. The epitaxial layer 121b can also be left behind as the common spreading layer for all the μLEDs in the array, in which case the conductive core of the barrier structure forms a permanent ohmic contact to layer 121b (not shown). The second side 121 as well as the top surface of the barrier structure 20 may further be processed and prepared for the bonding of the epitaxially grown layer stack 3.

The next steps can be applied differently. FIG. 18 illustrates the result of the bonding process, in which layer stack 3 is provided comprising an optional conductive layer 5, as well as an epitaxially grown converter layer 4. As described in the previous steps the layer stack 3 is processed separately including an optimized conversion layer for converting blue light emitted within the active region 13 of the respective μLEDs into red light. Conductive layer 5 forms an optional part of layer stack 3 and is located between the conversion layer 4 and the top surface or second side 121 of the respective μLEDs. This layer 5 is utilized in the absence of an epitaxially grown conductive spreading layer that serves as the common spreading and contact layer for all the μLEDs in the array. This layer 5 thus electrically connecting the conductive internal core of barrier structure 20 to the second side 121 of the respective μLEDs. It is of course to be understood, that layer stack 3 can include different or multiple conversion layers, wavelength selective layers as well as conductive layers and the like.

In an alternative processing step, the conductive layer 5 is applied, e.g., by growth or deposition on the second side 121 of the respective μLEDs and the conductive barrier structure 20. The conductive layer is configured for bonding the epitaxially grown conversion layer 4 to the layer stack 12a. in any case, epitaxially grown layer 4 forms an integral part of the arrangement.

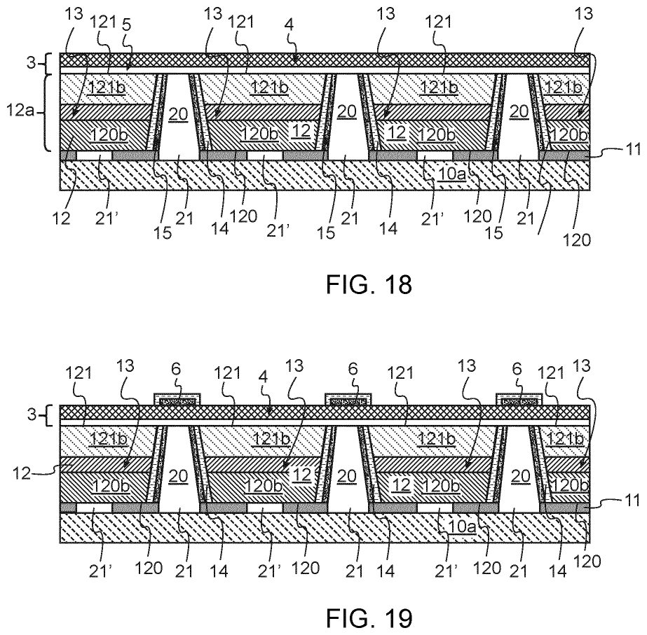

In the final step, a photoresist layer is applied to the conversion layer 4, subsequently structured to expose areas of the conversion layer above the barrier structure 20. In a subsequent step illustrated in FIG. 19, cover portions are applied to those exposed areas. The cover portions include conductive absorbing material and the reflecting layer on the respective sidewall surfaces. The resulting structure can then be removed from the temporary carrier 10a and arranged on a backplane substrate.

1.-69. (canceled)

70. An optoelectronic arrangement comprising:
at least one vertical optoelectronic device with a first side and a second side, wherein at least parts of the second side form a main emission surface, and wherein the optoelectronic device is configured to emit light of a first wavelength from the main emission surface;
an electrically conductive barrier structure at least partially surrounding the at least one vertical optoelectronic device and comprising sidewalls with a reflective surface, the reflective surface electrically isolated from sidewalls of the vertical optoelectronic device;
a layer stack arranged on and bonded to the main emission surface and comprising a first epitaxially grown converter layer configured to convert the light of the first wavelength to light of a second wavelength; and
an optional conductive layer arranged on the main emission surface and electrically connecting a second contact with the electrically conductive barrier structure.

71. The optoelectronic arrangement according to claim 70, wherein the optoelectronic arrangement comprises at least two vertical optoelectronic devices spaced apart by the electrically conductive barrier structure, and wherein the layer stack extends across the electrically conductive barrier structure covering the respective main emission surfaces of the at least two vertical optoelectronic devices.

72. The optoelectronic arrangement according to claim 70, wherein bonding of the layer stack to the main emission surface is facilitated by at least one of:
direct bonding of the layer stack onto the main emission surface;
a transparent conductive oxide; or
a dielectric layer between a bottom surface of the layer stack and the main emission surface.

73. The optoelectronic arrangement according to claim 70, wherein the layer stack comprises a second epitaxially grown converter layer configured to convert the light of the first wavelength into light of a third wavelength.

74. The optoelectronic arrangement according to claim 73, wherein the second epitaxially grown converter layer is arranged between the first epitaxially grown converter layer and the conductive layer or the main emission surface or above the first epitaxially grown converter layer.

75. The optoelectronic arrangement according to claim 70,
wherein material of the conductive layer forms a part of the first and/or second epitaxially grown converter layer, or
wherein the conductive layer forms a part of the at least one optoelectronic device, and/or
wherein the conductive layer comprises the same material as the first and/or second epitaxially grown converter layer.

76. The optoelectronic arrangement according to claim 70, wherein the layer stack comprises an outcoupling structure arranged on the first and/or second epitaxially grown converter layer facing away from the main emission surface.

77. The optoelectronic arrangement according to claim 70, wherein the first and/or second converter layer of the layer stack extends at least partially onto the electrically conductive barrier structure.

78. The optoelectronic arrangement according to claim 70,
wherein the conductive layer of the layer stack is structured in a region above the electrically conductive barrier structure, and/or
wherein the conductive layer of the layer stack comprises a conductive transparent material.

79. The optoelectronic arrangement according to claim 70, wherein the first and/or second epitaxially grown converter layer is structured in a region above the electrically conductive barrier structure.

80. The optoelectronic arrangement according to claim 70, wherein one of the conductive layer of the layer stack and the first and/or second epitaxially grown converter layer is structured in a region above the electrically conductive barrier structure.

81. The optoelectronic arrangement according to claim 70, wherein an area of the conductive layer of the layer stack is larger than the first and/or second epitaxially grown converter layer, and wherein a protruding part of the conductive layer is in electrical contact with the electrically conductive barrier structure.

82. The optoelectronic arrangement according to claim 70, wherein first and/or second epitaxially grown converter layer comprises at least one of:
a dielectric passivation layer covering an edge region above the electric conductive barrier structure,
a regrowth layer covering an edge region above the electric conductive barrier structure causing a shift in a bandgap close to the edge,
a quantum well intermixed area close to an edge region above the electric conductive barrier structure increasing a bandgap in the area,
a different doping profile close to an edge region above the electric conductive barrier structure changing a band bending in the area,
a quantum well intermixing in an area of the converter layer above the electric conductive barrier structure, or
an altered doping profile in an area of the converter layer above the electric conductive barrier structure changing a band bending in the area.

83. The optoelectronic arrangement according to claim 70, wherein the first and/or second epitaxially grown converter layer comprises InGaAlP, InGaAlN, InGaP or InGaN.

84. The optoelectronic arrangement according to claim 70, wherein the first epitaxially grown converter layer comprises a thickness sufficiently large to enable full conversion.

85. The optoelectronic arrangement according to claim 70,
wherein the main emission surface is larger than the first side, or
wherein the main emission surface is larger than a surface of the at least one optoelectronic device opposite the main emission surface.

86. The optoelectronic arrangement according to claim 70, wherein sidewalls of the barrier structure are tapered opening in a direction of the main emission surface.

87. The optoelectronic arrangement according to claim 70,
wherein the electrically conductive barrier structure comprise an internal conductive material and a reflective material covering sidewall surfaces, and/or
wherein the electrically conductive barrier structure is a reflective metal.

88. The optoelectronic arrangement according to claim 87, wherein the internal conductive material is different from the reflective material covering the sidewall surfaces of the at least one optoelectronic device.

89. The optoelectronic arrangement according to claim 70, wherein the barrier structure adjacent to the layer stack comprises at least partially a material configured to absorb the light of the first and/or second wavelength.

90. The optoelectronic arrangement according to claim 70, further comprising a cover portion arranged above the layer stack, optionally bonded thereto, and covering at least a portion of the layer stack adjacent to the electrically conductive barrier structure.

91. The optoelectronic arrangement according to claim 90,
wherein the cover portion is larger than a topmost surface of the electrically conductive barrier structure, thereby covering at least a portion of the second contact of the at least one vertical optoelectronic device, and/or
wherein the cover portion comprises at least one of:
tapered sidewalls, or
a material configured to absorb the light of the first and/or second wavelength,
a material configured to reflect the light of the first and/or second wavelength located on the sidewalls of the cover portion.

92. The optoelectronic arrangement according to claim 90, wherein the cover portion is conductive and connected to the electrically conductive barrier structure.

93. The optoelectronic arrangement according to claim 70, further comprising a first contact comprising a highly reflective material for the light of the first wavelength and optionally for the light of the second wavelength.

94. The optoelectronic arrangement according to claim 70, further comprising an insulation layer located on a side of the at least one vertical optoelectronic device and the electrically conductive barrier structure facing away from the main emission surface, wherein the insulation layer comprises a plurality of conductive via electrically connected to a first contact and the electrically conductive barrier structure, respectively.

95. The optoelectronic arrangement according to claim 70, further comprising a backplane substrate arranged on an insulating layer and comprising one of control circuitry and supply circuitry for the at least one vertical optoelectronic device.

96. The optoelectronic arrangement according to claim 70, wherein a first contact is connected to a p-side of the at least one vertical optoelectronic device and the second contact comprises an n-doped material and/or connected to a n-side of the at least one vertical optoelectronic device.

97. The optoelectronic arrangement according to claim 70, wherein at least one of the first or second contacts comprises a doped current distribution layer.

98. The Optoelectronic arrangement according to claim 70, wherein the at least one vertical optoelectronic device is based on a ZnSe, GaN, InGaN or AlGaN material configured to emit light with a wavelength smaller than 600 nm.

99. The optoelectronic arrangement according to claim 70, wherein the conductive layer is part of the layer stack or wherein the layer stack is bonded to the conductive layer, extending over a plurality of vertical optoelectronic devices.
